(19) United States
(12) Patent Application Publication
(10) Pub. No.: US 2023/0378224 A1
(43) Pub. Date: Nov. 23, 2023

(54) IMAGING CONTROL SUBSTRATE AND IMAGING CONTROL DEVICE

(71) Applicant: FUJIFILM Corporation, Tokyo (JP)

(72) Inventors: Yoshinori FURUTA, Saitama-shi (JP); Takuro ABE, Saitama-shi (JP)

(73) Assignee: FUJIFILM Corporation, Tokyo (JP)

(21) Appl. No.: 18/362,974

(22) Filed: Aug. 1, 2023

Related U.S. Application Data
(63) Continuation of application No. PCT/JP2021/046924, filed on Dec. 20, 2021.

(30) Foreign Application Priority Data
Feb. 26, 2021 (JP) 2021-030089

(51) Int. Cl. H01L 27/146

(52) U.S. Cl. CPC H01L 27/14636; H01L 27/14634

(57) ABSTRACT

An imaging control substrate includes: a processor having a plurality of differential signal input terminals into which a signal output from an imaging element is to be input; a power control circuit that controls electric power supplied to the imaging element; a first connector to which a power supply line that supplies the electric power controlled by the power control circuit to an imaging substrate mounted with the imaging element is connected; a second connector to which only a differential signal transmission line that transmits an output signal of the imaging element is connected; and a wiring group that connects the second connector and the plurality of differential signal input terminals.

### CROSS REFERENCE TO RELATED APPLICATION

This is a continuation of International Application No. PCT/JP2021/046924 filed on Dec. 20, 2021, and claims priority from Japanese Patent Application No. 2021-030089 filed on Feb. 26, 2021, the entire disclosures of which are incorporated herein by reference.

### BACKGROUND OF THE INVENTION

### 1. Field of the Invention

The present invention relates to an imaging control substrate and an imaging control device.

### 2. Description of the Related Art

JP2020-64281A describes an imaging apparatus including an imaging element that converts an optical image of a subject into an electrical signal, a movable unit that holds the imaging element and can be displaced in a direction different from an optical axis of an imaging optical system, a control unit on which a circuit that transmits an imaging signal output from the imaging element is mounted, a first flexible substrate that electrically connects the movable unit and the control unit, and a second flexible substrate that electrically connects the movable unit and the control unit.

JP2019-200349A describes an imaging apparatus including a housing, a movable unit that can move in a direction orthogonal to an optical axis with respect to the housing, a substrate that is fixed to the movable unit and mounts an imaging element, a flexible printed circuit substrate that is electrically connected to the substrate, and a control substrate that is fixed to the housing, is disposed in parallel to the substrate with respect to a plane orthogonal to the optical axis, and is electrically connected to the substrate via the flexible printed circuit substrate.

### SUMMARY OF THE INVENTION

An object of the present invention is to provide an imaging control substrate that is compatible with various imaging elements and an imaging control device including the imaging control substrate.

An imaging control substrate according to an aspect of the present invention comprises a processor having a plurality of differential signal input terminals into which a signal output from an imaging element is to be input, a power control circuit that controls power supplied to the imaging element, a first connector to which a power supply line that supplies the power controlled by the power control circuit to an imaging substrate mounted with the imaging element is connected, a second connector to which only a differential signal transmission line that transmits an output signal of the imaging element is connected, and a wiring group that connects the second connector and the plurality of differential signal input terminals.

An imaging control device according to an aspect of the present invention comprises the imaging control substrate, the imaging substrate mounted with the imaging element, and a flexible substrate that connects the imaging substrate and the imaging control substrate.

According to the present invention, it is possible to provide the imaging control substrate that is compatible with various imaging elements and the imaging control device including the imaging control substrate.

### BRIEF DESCRIPTION OF THE DRAWINGS

FIG. 1 is a diagram showing a schematic configuration of an electronic apparatus 1 including an imaging control device 3 which is an embodiment of an imaging control device according to the present invention.

FIG. 2 is a schematic diagram showing a detailed configuration example of an imaging substrate 20, an imaging control substrate 10, and an FPC substrate FS1 in the imaging control device 3 shown in FIG. 1.

FIG. 3 is a schematic diagram corresponding to FIG. 2 showing a configuration of another model of the electronic apparatus 1 shown in FIG. 1.

FIG. 4 is a schematic diagram showing an imaging control substrate 10A which is a first modification example of the imaging control substrate 10.

FIG. 5 is a schematic diagram showing an imaging control substrate 10B which is a second modification example of the imaging control substrate 10.

FIG. 6 is a schematic diagram showing an imaging control substrate 10C which is a third modification example of the imaging control substrate 10.

FIG. 7 is a schematic diagram showing an imaging control substrate 10D which is a fourth modification example of the imaging control substrate 10.

### DESCRIPTION OF THE PREFERRED EMBODIMENTS

Hereinafter, embodiments of the present invention will be described with reference to drawings.

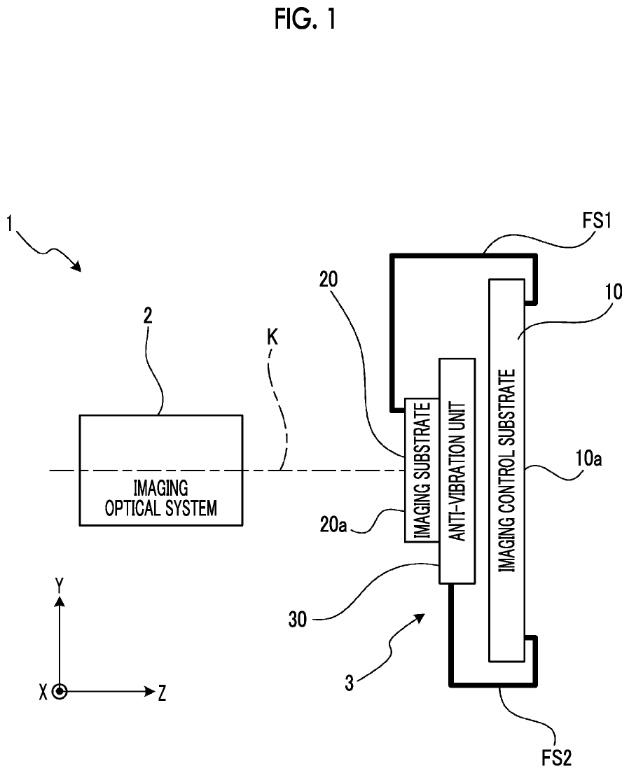

FIG. 1 is a diagram showing a schematic configuration of an electronic apparatus 1 including an imaging control device 3 which is an embodiment of an imaging control device according to the present invention. The electronic apparatus 1 is an electronic apparatus having an imaging function, such as a digital camera, a tablet terminal with a camera, and a smartphone with a camera.

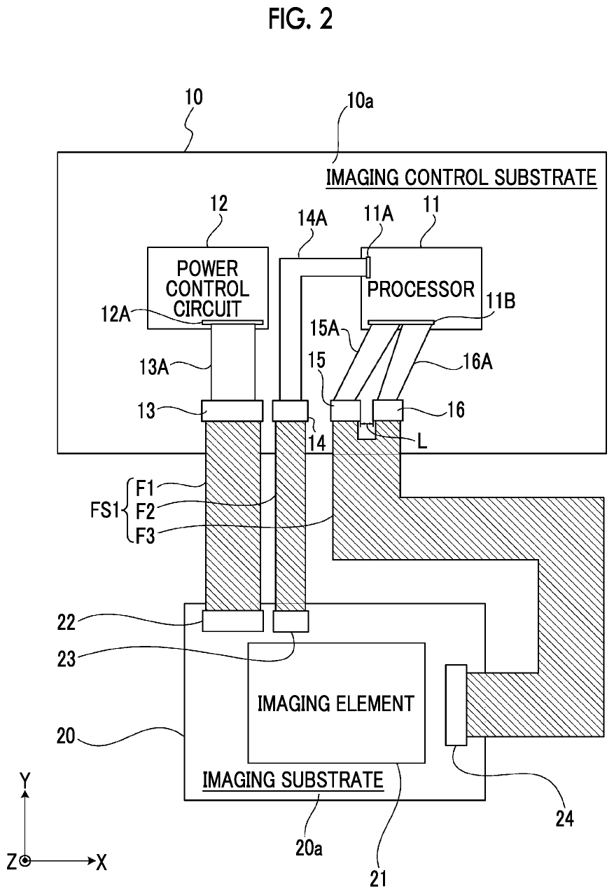

The electronic apparatus 1 comprises an imaging optical system 2 including a lens, a stop, and the like, and an imaging control device 3 including an imaging element 21 (refer to FIG. 2) that images a subject through the imaging optical system 2. Hereinafter, a direction along an optical axis K of the imaging optical system 2 is described as a direction Z. Further, two directions orthogonal to the direction Z and orthogonal to each other are described as a direction X and a direction Y.

The imaging control device 3 comprises an imaging control substrate 10, an imaging substrate 20 mounted with the imaging element 21, such as a charge coupled device (CCD) image sensor or a complementary metal oxide semiconductor (CMOS) image sensor, an anti-vibration unit 30, and flexible printed circuit substrates (hereinafter, referred to as FPC substrates) FS1 and FS2. The imaging substrate 20 and the imaging control substrate 10 are electrically connected by the FPC substrate FS1. The anti-vibration unit 30 and the imaging control substrate 10 are electrically connected by the FPC substrate FS2. In the imaging control device 3, the anti-vibration unit 30 and the FPC substrate FS2 are not essential and may be omitted.

The anti-vibration unit 30 is a unit that moves the imaging substrate 20 including the imaging element 21 in a plane perpendicular to the optical axis K of the imaging optical system 2 to prevent blurring of a subject image formed on the imaging element 21.

The imaging substrate 20, the anti-vibration unit 30, and the imaging control substrate 10 are disposed side by side in the direction Z from an imaging optical system 2 side in this order.

The imaging substrate 20 is a plate-shaped substrate perpendicular to the direction Z. A surface on the imaging optical system 2 side of both edge surfaces of the imaging substrate 20 in the direction Z is described as a main surface 20a. The imaging control substrate 10 is a plate-shaped substrate perpendicular to the direction Z. A surface on a side opposite to the imaging optical system 2 side of both edge surfaces of the imaging control substrate 10 in the direction Z is described as a main surface 10a.

The FPC substrate FS1 is a flexible substrate including a plurality of conductive wires and is configured to have an elongated shape. The FPC substrate FS1 has a plug connected to each of an imaging substrate connector provided on the main surface 20a of the imaging substrate 20 and a control substrate connector provided on the main surface 10a of the imaging control substrate 10. As shown in FIG. 2, the FPC substrate FS1 electrically connects the imaging substrate connector and the control substrate connector in a state of being folded back from the main surface 20a of the imaging substrate 20 toward the main surface 10a of the imaging control substrate 10.

The FPC substrate FS2 is a flexible substrate including a plurality of conductive wires and is configured to have an elongated shape. The FPC substrate FS2 has an FPC plug connected to each of an anti-vibration unit connector provided in the anti-vibration unit 30 and the control substrate connector provided in the main surface 10a of the imaging control substrate 10. As shown in FIG. 2, the FPC substrate FS2 electrically connects the anti-vibration unit connector and the control substrate connector in a state of being folded back from the anti-vibration unit 30 toward the main surface 10a of the imaging control substrate 10.

FIG. 2 is a schematic diagram showing a detailed configuration example of the imaging substrate 20, the imaging control substrate 10, and the FPC substrate FS1 in the imaging control device 3 shown in FIG. 1. FIG. 2 shows a state in which the FPC substrate FS1 is developed such that the main surface 20a of the imaging substrate 20 and the main surface 10a of the imaging control substrate 10 face the same direction.

The imaging element 21, a first imaging substrate connector 22, a second imaging substrate connector 23, and a third imaging substrate connector 24 are provided on the main surface 20a of the imaging substrate 20. The imaging element 21 is chipped and has a plurality of terminals. The terminals included in the imaging element 21 include a plurality of power supply terminals for receiving power supply from the imaging control substrate 10, a plurality of control terminals for receiving control signals from the imaging control substrate 10, and a plurality of output terminals of outputting an imaging signal and the like.

The first imaging substrate connector 22 includes terminals respectively connected to the plurality of power supply terminals of the imaging element 21. The second imaging substrate connector 23 includes terminals respectively connected to the plurality of control terminals of the imaging element 21. The third imaging substrate connector 24 includes terminals respectively connected to the plurality of output terminals of the imaging element 21.

The plurality of output terminals of the imaging element 21 are connected with a plurality of differential signal transmission lines having two signal lines as a pair, which employ a transmission method such as low voltage differential signal (LVDS). The other ends of the plurality of differential signal transmission lines are respectively connected to the terminals included in the third imaging substrate connector 24. As an example, the imaging element 21 is provided with 32 output terminals. That is, the output terminals of the imaging element 21 and the terminals of the third imaging substrate connector 24 are connected by a wiring group consisting of 16 differential signal transmission lines. The transmission method may include mobile industry processor interface (MIPI) (registered trademark) or scalable low voltage signaling with embedded clock (SLVS-EC) (registered trademark), in addition to LVDS.

A chipped processor 11, a chipped power control circuit 12, a first control substrate connector 13, a second control substrate connector 14, a third control substrate connector 15, and a fourth control substrate connector 16 are provided on the main surface 10a of the imaging control substrate 10.

The processor described in the present specification includes a central processing unit (CPU) that is a general-purpose processor performing various types of processing by executing a program, a programmable logic device (PLD) that is a processor of which a circuit configuration can be changed after manufacturing like a field programmable gate array (FPGA), or a dedicated electric circuit or the like that is a processor having a circuit configuration dedicatedly designed to execute a specific type of processing like an application specific integrated circuit (ASIC). More specifically, a structure of the processor is an electric circuit in which circuit elements such as semiconductor elements are combined.

The power control circuit 12 controls the supply of power generated by a power supply circuit (not shown) built into the electronic apparatus 1 to the imaging substrate 20. The power control circuit 12 includes a terminal group 12A including a plurality of power control terminals for connection with the imaging substrate 20. The first control substrate connector 13 includes terminals connected to each power control terminal of the power control circuit 12. Each power control terminal of the power control circuit 12 and each terminal of the first control substrate connector 13 are connected by a wiring group 13A provided on the imaging control substrate 10.

The processor 11 controls the imaging element 21 and the anti-vibration unit 30. Specifically, the processor 11 transmits the control signal for driving the imaging element 21 to the imaging element 21 to perform imaging control, transmits the control signal for driving the anti-vibration unit 30 to the anti-vibration unit 30 to perform anti-vibration control, or acquires an output signal of the imaging element 21 to process the acquired output signal.

The processor 11 comprises a terminal group 11A including a plurality of control signal output terminals for outputting the control signal for controlling the imaging element 21 and a terminal group 11B including a plurality of differential signal input terminals for inputting the output signal of the imaging element 21. The plurality of control signal output terminals included in the terminal group 11A are arranged in the direction Y. The plurality of differential signal input terminals included in the terminal group 11B are arranged in the direction X. In the present embodiment, the number of differential signal input terminals included in the terminal group 11B is set to 32, as an example.

Each control signal output terminal included in the terminal group 11A of the processor 11 and each terminal of the second control substrate connector 14 are connected by a wiring group 14A provided on the imaging control substrate 10.

A part of all the differential signal input terminals included in the terminal group 11B of the processor 11 and each terminal of the third control substrate connector 15 are connected by a wiring group 15A provided on the imaging control substrate 10.

The rest of all the differential signal input terminals other than the part thereof included in the terminal group 11B of the processor 11 and each terminal of the fourth control substrate connector 16 are connected by a wiring group 16A provided on the imaging control substrate 10.

In the present embodiment, the number of terminals of the third control substrate connector 15 is set to 16 and the number of terminals of the fourth control substrate connector 16 is set to 16, as an example. Therefore, the total number of differential signal transmission lines that can be respectively connected to the third control substrate connector 15 and the fourth control substrate connector 16 is eight.

An arrangement direction of the plurality of terminals included in the third control substrate connector 15 is the direction X. Further, an arrangement direction of the plurality of terminals included in the fourth control substrate connector 16 is the direction X. That is, the arrangement direction of the plurality of terminals included in the third control substrate connector 15 is the same as the arrangement direction of the differential signal input terminals of the processor 11 connected to the plurality of terminals by the wiring group 15A. Similarly, the arrangement direction of the plurality of terminals included in the fourth control substrate connector 16 is the same as the arrangement direction of the differential signal input terminals of the processor 11 connected to the plurality of terminals by the wiring group 16A.

As described above, by making the arrangement direction of the plurality of terminals included in the third control substrate connector 15 (the fourth control substrate connector 16) the same as the arrangement direction of the differential signal input terminals of the processor 11 connected to the plurality of terminals, it is possible to facilitate routing of the wiring group 15A (wiring group 16A) and thus reduce the manufacturing cost of the imaging control substrate 10.

The FPC substrate FS1 that electrically connects the imaging control substrate 10 and the imaging substrate 20 includes a first FPC substrate F1, a second FPC substrate F2, and a third FPC substrate F3.

The first FPC substrate F1 connects each terminal of the first control substrate connector 13 of the imaging control substrate 10 to each terminal of the first imaging substrate connector 22 of the imaging substrate 20. That is, each conductive wire included in the first FPC substrate F1 is a power supply line that supplies the power controlled by the power control circuit 12 of the imaging control substrate 10 to the imaging substrate 20.

The second FPC substrate F2 connects each terminal of the second control substrate connector 14 of the imaging control substrate 10 to each terminal of the second imaging substrate connector 23 of the imaging substrate 20. That is, each conductive wire included in the second FPC substrate F2 is a control signal line that transmits the control signal output from the processor 11 of the imaging control substrate 10 to the imaging substrate 20.

The third FPC substrate F3 connects each terminal of the third control substrate connector 15 of the imaging control substrate 10 and each terminal of the fourth control substrate connector 16 to each terminal of the third imaging substrate connector 24 of the imaging substrate 20. That is, each conductive wire included in the third FPC substrate F3 is the differential signal transmission line that transmits the output signal of the imaging element 21 to the imaging control substrate 10. The number of differential signal transmission lines included in the third FPC substrate F3 is 16. The number of terminals included in the fourth control substrate connector 16 is 56 in an LVDS system and 50 in an SLVS-EC system, which includes transmission lines for GND and a clock signal in addition to the 16 differential signal transmission lines.

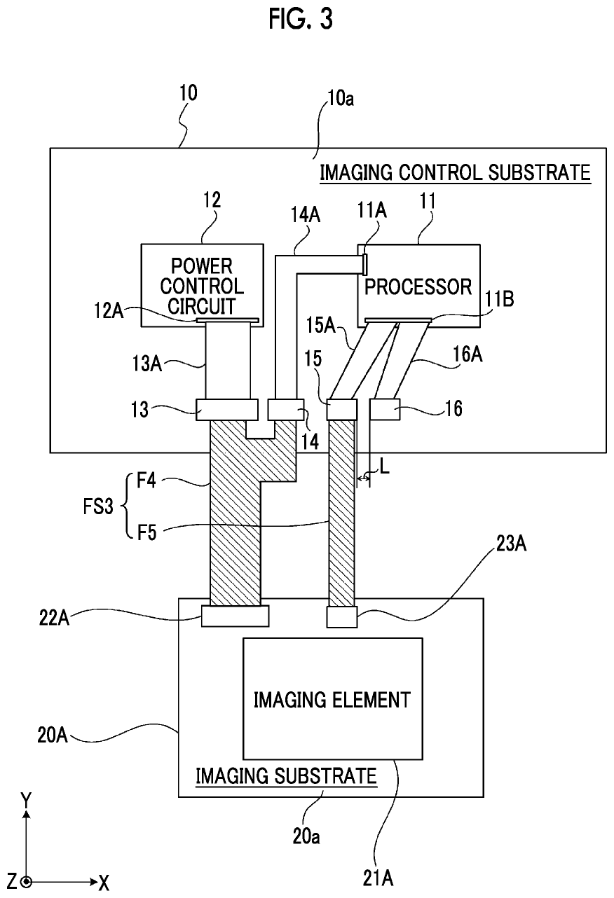

As the electronic apparatus 1 configured as described above, a plurality of models having different configurations of the imaging control device 3 are manufactured. Even in a case where the model of the electronic apparatus 1 is different, the configuration of the imaging control substrate 10 is the same. FIG. 3 is a schematic diagram corresponding to FIG. 2 showing a configuration of another model of the electronic apparatus 1 shown in FIG. 1. FIG. 3 has the same configuration as that of FIG. 2 except that the imaging substrate 20 is changed to an imaging substrate 20A and the FPC substrate FS1 is changed to an FPC substrate FS3.

The imaging substrate 20A shown in FIG. 3 comprises an imaging element 21A, a fourth imaging substrate connector 22A, and a fifth imaging substrate connector 23A. A power supply current required for the operation of the imaging element 21A is different from that of the imaging element 21. Specifically, the power supply current required for the operation of the imaging element 21A is smaller than the power supply current required for the operation of the imaging element 21. Further, the number of output terminals of the imaging element 21A is smaller than that of the imaging element 21. As an example, the number of output terminals included in the imaging element 21A is half the number of output terminals of the imaging element 21, that is, 16.

Each terminal of the fourth imaging substrate connector 22A is connected to the plurality of power supply terminals and the plurality of control terminals included in the imaging element 21A. Each terminal of the fifth imaging substrate connector 23A is connected to the plurality of output terminals included in the imaging element 21A.

The FPC substrate FS3 comprises a fourth FPC substrate F4 and a fifth FPC substrate F5.

The fourth FPC substrate F4 connects each terminal of the first control substrate connector 13 and each terminal of the second control substrate connector 14 of the imaging control substrate 10 to each terminal of the fourth imaging substrate connector 22A of the imaging substrate 20A. That is, a conductive wire group included in the fourth FPC substrate F4 is configured of the power supply line that supplies the power controlled by the power control circuit 12 of the imaging control substrate 10 to the imaging substrate 20A and the control signal line that transmits the control signal output from the processor 11 of the imaging control substrate 10 to the imaging substrate 20A.

The power supply current required for the operation of the imaging element 21A is smaller than the power supply current required for the operation of the imaging element 21. On the other hand, the power control circuit 12 is common between FIGS. 2 and 3, and the power output from the first control substrate connector 13 is the same in FIGS. 2 and 3. For this reason, an electric resistance value of the power supply line included in the fourth FPC substrate F4 is configured to be larger than an electric resistance value of the power supply line included in the first FPC substrate F1 shown in FIG. 2 such that the power supply current having magnitude suitable for the imaging element 21A is supplied to the imaging element 21A. Specifically, the power supply line included in the fourth FPC substrate F4 is thinner than the power supply line included in the first FPC substrate F1 shown in FIG. 2.

The fifth FPC substrate F5 connects each terminal of the third control substrate connector 15 to each terminal of the fifth imaging substrate connector 23A. That is, each conductive wire included in the fifth FPC substrate F5 is the differential signal transmission line that transmits the output signal of the imaging element 21A to the imaging control substrate 10. In the above example, the number of differential signal transmission lines included in the fifth FPC substrate F5 is eight.

In the electronic apparatus 1 of the model shown in FIG. 3, the fourth control substrate connector 16 of the imaging control substrate 10 is not used. For this reason, no wiring line is connected to the fourth control substrate connector 16, or a plug that short-circuits the terminals of the fourth control substrate connector 16 is attached. Therefore, in the electronic apparatus 1 of the model shown in FIG. 3, the output signal of the imaging element 21A is input to only 16 of the 32 differential signal input terminals of the processor 11. The program to be stored in the memory of the processor 11 is set to be different for each model. Accordingly, it is not necessary to change the imaging control substrate 10 even in the electronic apparatuses 1 having different models.

As described above, in the electronic apparatus 1, the configuration of the imaging substrate is different for each model, and the power supply current required for the operation of the imaging element mounted on the imaging substrate is also different. Therefore, an allowable current value (maximum current value that can flow) of the first control substrate connector 13 of the imaging control substrate 10 is set to the same value as a power supply current of an imaging element whose power supply current required for the operation is maximized, among imaging elements mounted on all models of the electronic apparatus 1. Accordingly, even in a case where the imaging element is different for each model, the imaging element is connected to the imaging control substrate 10 and the power supplied can be normally controlled.

As described above, with the electronic apparatus 1, it is not necessary to change the configuration of the imaging control substrate 10 for each model. Therefore, the manufacturing cost can be reduced. In the imaging control substrate 10, the third control substrate connector 15 and the fourth control substrate connector 16 are dedicated connectors for connecting the differential signal transmission lines. For this reason, the imaging element can be connected to the processor 11 even in an imaging element in which the required number of differential signal transmission lines is different only by changing the number of differential signal transmission lines connected to the dedicated connector. Therefore, it is not necessary to optimize the configuration of the imaging control substrate 10 for each of various imaging elements, and thus the manufacturing cost of the imaging control substrate 10 can be reduced.

In the imaging control substrate 10, the first control substrate connector 13 is the dedicated connector for connecting the power supply line, and the second control substrate connector 14 is the dedicated connector for connecting the control signal line. Even in a case where the first control substrate connector 13 and the second control substrate connector 14 are integrated into one connector, it is possible to obtain the effect of eliminating the need for optimizing the configuration of the imaging control substrate 10 for each of various imaging elements by changing the configuration of the FPC substrate connected to the connector. However, with the individual providing of the first control substrate connector 13 and the second control substrate connector 14, it is possible to facilitate routing of the wiring group 13A and the wiring group 14A and thus reduce the manufacturing cost of the imaging control substrate 10. Further, a configuration can be employed in which the second control substrate connector 14 is disposed between the first control substrate connector 13 and the third control substrate connector 15 and the fourth control substrate connector 16. With the above configuration, it is possible to increase a distance between the differential signal transmission line and the power supply line and thus improve the quality of the output signal of the imaging element input to the processor 11.

Each of the third control substrate connector 15 and the fourth control substrate connector 16 includes a terminal group to which the plurality of differential signal transmission lines are connected. For this reason, the wiring line is dense around each of the third control substrate connector 15 and the fourth control substrate connector 16. Therefore, in order to facilitate the routing of the wiring group 15A and the wiring group 16A, it is desirable to increase a distance L (refer to FIGS. 2 and 3) between the third control substrate connector 15 and the fourth control substrate connector 16 in the direction X.

For example, the distance L is set to be equal to or larger than a value obtained by multiplying a value of ¼ of the total number of connectable differential signal transmission lines of a control substrate connector whose total number is maximum, of the third control substrate connector 15 and the fourth control substrate connector 16, by a width of the differential signal transmission line. With the above setting, it is possible to facilitate the routing of the wiring group 15A and the wiring group 16A. In the above example, the total number of differential signal transmission lines that can be connected to each of the third control substrate connector 15 and the fourth control substrate connector 16 is eight. For this reason, the distance L may be set to be twice or more the width of the differential signal transmission line.

Alternatively, the distance L is set to be equal to or larger than half of a width in the terminal arrangement direction (direction X) of a control substrate connector whose width is maximum, of the third control substrate connector 15 and the fourth control substrate connector 16. With the above setting, it is possible to facilitate the routing of the wiring group 15A and the wiring group 16A. In the above example, the widths of the third control substrate connector 15 and the fourth control substrate connector 16 are the same. For this reason, the distance L may be set to be equal to or larger than half of the width in the direction X of any one of the third control substrate connector 15 or the fourth control substrate connector 16.

Alternatively, the distance L is set to be equal to or larger than a width in the direction X of a region whose width is maximum, of regions where the differential signal input terminals of the processor 11 connected to each of the third control substrate connector 15 and the fourth control substrate connector 16 are arranged. With the above setting, it is possible to facilitate the routing of the wiring group 15A and the wiring group 16A. In the above example, the width of the region where the differential signal input terminals connected to the third control substrate connector 15 are arranged is the same as the width of the region where the differential signal input terminals connected to the fourth control substrate connector 16 are arranged. For this reason, the distance L may be set to be equal to or larger than the width of any one of these two regions.

The example has been described in which two connectors for connecting the differential signal transmission lines, the third control substrate connector 15 and the fourth control substrate connector 16, are provided on the imaging control substrate 10. However, three or more connectors for connecting the differential signal transmission lines may be provided. Even in a case where three or more of these connectors are provided, with setting of a distance between two adjacent connectors in the same manner as the above distance L, it is possible to facilitate the routing of the wiring group and thus reduce the manufacturing cost. Further, it becomes possible to cope with an increase in the number of models of the electronic apparatus 1.

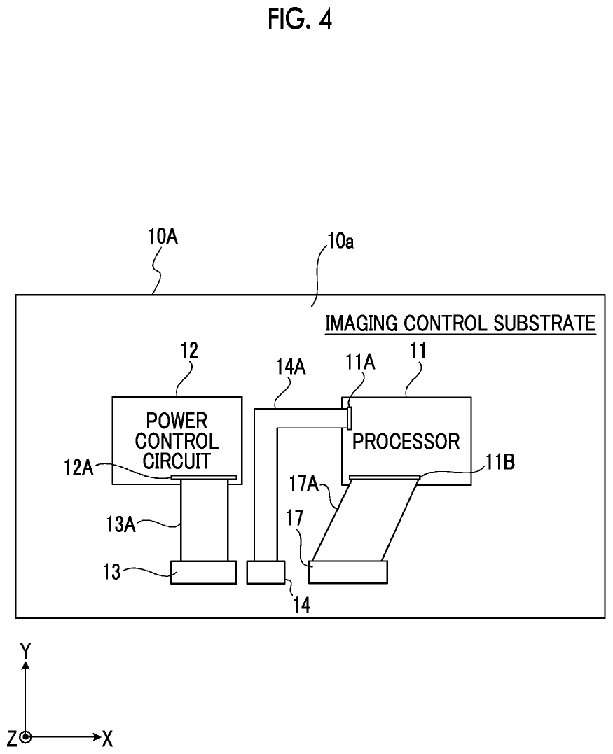

FIG. 4 is a schematic diagram showing an imaging control substrate 10A which is a first modification example of the imaging control substrate 10. The imaging control substrate 10A has the same configuration as the imaging control substrate 10 except that the third control substrate connector 15 and the fourth control substrate connector 16 are integrated and changed to a fifth control substrate connector 17. Thirty-two terminals are arranged in the direction X in the fifth control substrate connector 17, and the 32 terminals and the 32 differential signal input terminals included in the processor 11 are connected by a wiring group 17A.

With changing in the number of differential signal transmission lines on an FPC substrate side, which is connected to the terminal of the fifth control substrate connector 17, according to the model of the electronic apparatus 1, a configuration of the imaging control substrate 10A is also compatible with different imaging elements without changing the imaging control substrate 10A.

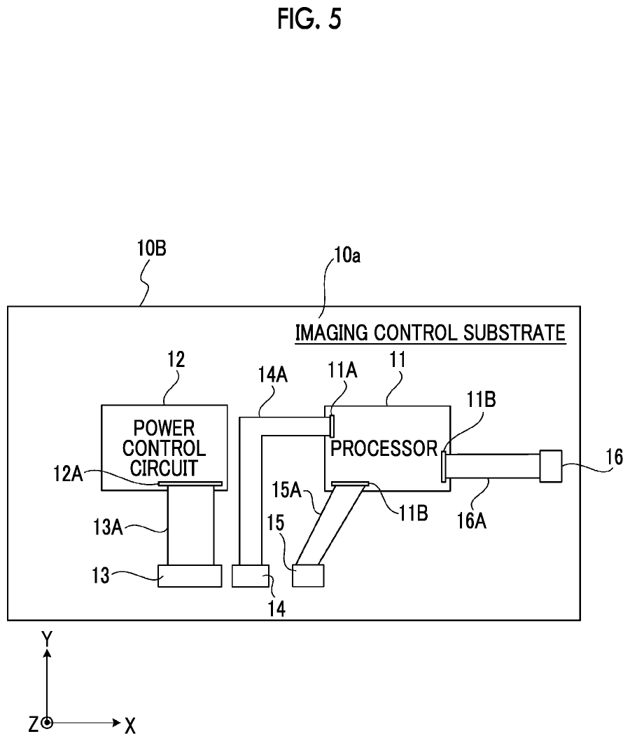

FIG. 5 is a schematic diagram showing an imaging control substrate 10B which is a second modification example of the imaging control substrate 10. The imaging control substrate 10B has the same configuration as the imaging control substrate 10 except that the terminal group 11B is divided into two and the positions of the fourth control substrate connector 16 and the wiring group 16A are changed.

One of the two divided terminal groups 11B is formed to extend in the direction X along a long side of the rectangular processor 11. The other of the two divided terminal groups 11B is formed to extend in the direction Y along a short side of the rectangular processor 11. The fourth control substrate connector 16 is formed to extend in the direction Y along the short side of the processor 11. An extending direction of the terminal group 11B is the same as the arrangement direction of the plurality of differential signal input terminals included in the terminal group 11B. An extending direction of the fourth control substrate connector 16 is the same as the arrangement direction of the plurality of terminals included in the fourth control substrate connector 16.

With the imaging control substrate 10B, similarly to the imaging control substrate 10, the arrangement direction of the plurality of terminals included in the third control substrate connector 15 matches the arrangement direction of the differential signal input terminals of the processor 11 connected to the plurality of terminals. Further, the arrangement direction of the plurality of terminals included in the fourth control substrate connector 16 matches the arrangement direction of the differential signal input terminals of the processor 11 connected to the plurality of terminals. As described above, since the arrangement direction of the connector terminals is the same as the arrangement direction of the differential signal input terminals, it is possible to shorten wiring lengths of the wiring group 15A and the wiring group 16A and thus improve quality of a differential signal input to the processor 11. Further, it is possible to facilitate the routing of the wiring group 15A and the wiring group 16A and thus reduce the manufacturing cost of the imaging control substrate 10B.

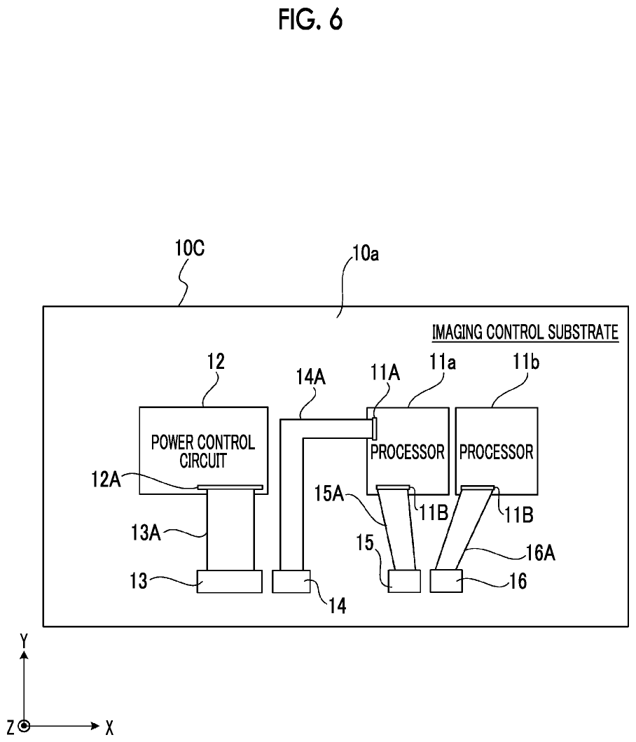

FIG. 6 is a schematic diagram showing an imaging control substrate 10C which is a third modification example of the imaging control substrate 10. The imaging control substrate 10C has substantially the same configuration as the imaging control substrate 10 except that a plurality (two in example of FIG. 6) of processors 11a and 11b are included instead of the processor 11.

The processor 11a is provided with the terminal group 11B in which the plurality of differential signal input terminals are arranged in the direction X, and the terminal group 11B and the third control substrate connector 15 are connected by the wiring group 15A. The processor 11a is provided with the terminal group 11A in which the plurality of control terminals are arranged in the direction Y, and the terminal group 11A and the second control substrate connector 14 are connected by the wiring group 14A. The processor 11b is provided with the terminal group 11B in which the plurality of differential signal input terminals are arranged in the direction X, and the terminal group 11B and the fourth control substrate connector 16 are connected by the wiring group 16A.

As described above, even in a case where the plurality of processors are present, since the arrangement direction of the terminals of the connector connected to the FPC substrate is the same as the arrangement direction of the differential signal input terminals, it is possible to shorten wiring lengths of the wiring group 15A and the wiring group 16A and thus improve quality of signals input to the processor 11a and the processor 11b. Further, it is possible to facilitate the routing of the wiring group 15A and the wiring group 16A and thus reduce the manufacturing cost of the imaging control substrate 10C.

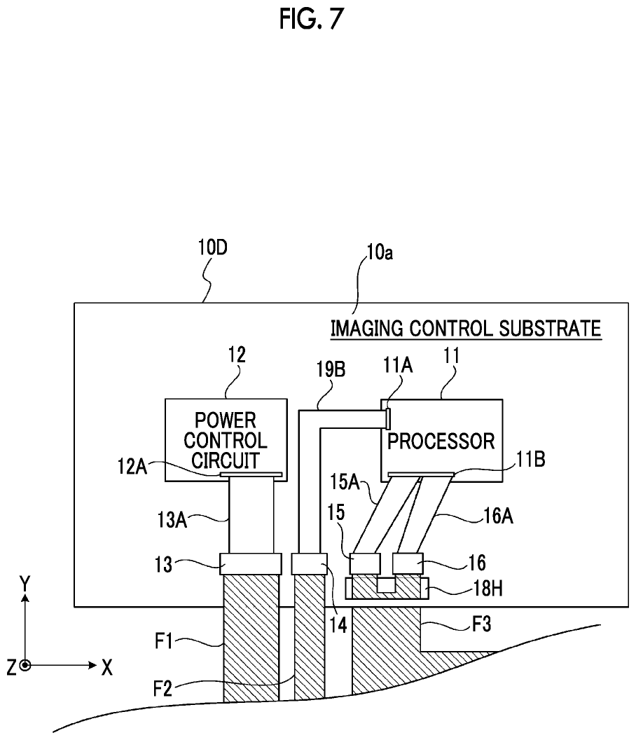

FIG. 7 is a schematic diagram showing an imaging control substrate 10D which is a fourth modification example of the imaging control substrate 10. The imaging control substrate 10D is different from the imaging control substrate 10 in that an opening 18H is included in a region between an edge on one side (lower side in drawing) of the direction Y and the third control substrate connector 15 and the fourth control substrate connector 16.

As shown in FIG. 7, a plug of the third FPC substrate F3 is inserted into the opening 18H from a surface side opposite to the main surface 10a of the imaging control substrate 10D and connected to the third control substrate connector 15 and the fourth control substrate connector 16. As described above, with the configuration in which the third FPC substrate F3, the third control substrate connector 15, and the fourth control substrate connector 16 are connected through the opening 18H, it is possible to shorten a length of the differential signal transmission line included in the third FPC substrate F3. Accordingly, it is possible to improve quality of a signal input to the processor 11.

As shown in FIG. 1, the anti-vibration unit 30 and the imaging control substrate 10 are connected by the FPC substrate FS2. For this reason, the imaging control substrate 10 is provided with a connector for anti-vibration (not shown) for the connection with the anti-vibration unit 30. The connector for anti-vibration may be divided into a plurality of parts, and each connector and the processor 11 may be connected by a wiring group. Further, with connection of only necessary connectors to the anti-vibration unit 30 according to the model of the electronic apparatus 1, a structure of the imaging control substrate 10 does not need to be changed even in a case where a structure of the anti-vibration unit 30 is changed. As a result, it is possible to reduce the manufacturing cost of the electronic apparatus 1.

As described above, at least the following matters are described in the present specification. Although the components and the like corresponding to the above embodiments are shown in parentheses, the present invention is not limited thereto.

(1)

An imaging control substrate (imaging control substrate 10, 10A to 10D) comprising:

a processor (processor 11) having a plurality of differential signal input terminals into which a signal output from an imaging element (imaging element 21, imaging element 21A) is to be input;

a power control circuit (power control circuit 12) that controls power supplied to the imaging element;

a first connector (first control substrate connector 13) to which a power supply line that supplies the power controlled by the power control circuit to an imaging substrate (imaging substrate 20) mounted with the imaging element is connected;

a second connector (third control substrate connector 15 and fourth control substrate connector 16, or fifth control substrate connector 17) to which only a differential signal transmission line that transmits an output signal of the imaging element is connected; and

a wiring group (wiring group 15A and wiring group 16A, or wiring group 17A) that connects the second connector and the plurality of differential signal input terminals.

(2)

The imaging control substrate according to (1),

wherein the first connector is connected only to the power control circuit.

(3)

The imaging control substrate according to (2),

wherein the imaging substrate mounted with any one of a plurality of imaging elements (imaging element 21 and imaging element 21A) having different power supply currents is connectable, and

an allowable current value of the first connector is equal to or larger than a current value required to be supplied to an imaging element, among the plurality of imaging elements, to which a largest power supply current needs to be supplied.

(4)

The imaging control substrate according to (2) or (3), further comprising:

a third connector (second control substrate connector 14) connected to a terminal of the processor that outputs a control signal of the imaging element.

(5)

The imaging control substrate according to (4),

wherein the third connector is disposed between the first connector and the second connector.

(6)

The imaging control substrate according to any one of (1) to (5),

wherein a plurality of the second connectors (third control substrate connector 15 and fourth control substrate connector 16) are provided, and

a distance (distance L) between two adjacent second connectors is equal to or larger than a value obtained by multiplying a value of ¼ of a total number of connectable differential signal transmission lines of a second connector whose total number is maximum, of the two adjacent second connectors, by a width of the differential signal transmission line.

(7)

The imaging control substrate according to any one of (1) to (5),

wherein a plurality of the second connectors (third control substrate connector 15 and fourth control substrate connector 16) are provided, and

a distance (distance L) between two adjacent second connectors is equal to or larger than half of a width in a terminal arrangement direction of a second connector whose width is maximum, of the two adjacent second connectors.

(8)

The imaging control substrate according to any one of (1) to (5),

wherein a plurality of the second connectors (third control substrate connector 15 and fourth control substrate connector 16) are provided, and

a distance (distance L) between two adjacent second connectors is equal to or larger than a width of a region whose width is maximum, of regions where the plurality of differential signal input terminals connected to each of the two adjacent second connectors are arranged.

(9)

The imaging control substrate according to any one of (1) to (8),

wherein an arrangement direction of a plurality of terminals included in the second connector matches an arrangement direction of the plurality of differential signal input terminals connected to the plurality of terminals.

(10)

The imaging control substrate according to any one of (1) to (9),

wherein a plurality of the processors (processors 11a and 11b) are provided, and

an arrangement direction of the plurality of differential signal input terminals of each of the plurality of processors matches an arrangement direction of a plurality of terminals included in the second connector connected to the plurality of differential signal input terminals.

(11)

The imaging control substrate according to any one of (1) to (10), further comprising:

an opening (opening 18H) provided in a region between an edge of the imaging control substrate and the second connector,

wherein the differential signal transmission line is inserted into the opening.

(12)

An imaging control device comprising:

the imaging control substrate according to any one of (1) to (11);

the imaging substrate mounted with the imaging element; and

a flexible substrate (FPC substrate FS1) that connects the imaging substrate and the imaging control substrate.

(13)

The imaging control device according to (12),

wherein the imaging control substrate is provided with a plurality of the second connectors (third control substrate connector 15 and fourth control substrate connector 16), and

the flexible substrate electrically connects at least one of the plurality of second connectors and a connector provided on the imaging substrate.

While various embodiments are described above with reference to the drawings, the present invention is not limited to such examples. It is apparent that those skilled in the art may perceive various modification examples or correction examples within the scope disclosed in the claims, and those examples are also understood as falling within the technical scope of the present invention. Further, any combination of various components in the embodiment may be used without departing from the gist of the invention.

The present application is based on Japanese Patent Application (JP2021-030089) filed on Feb. 26, 2021, the content of which is incorporated in the present application by reference.

### EXPLANATION OF REFERENCES

1: electronic apparatus

2: imaging optical system

3: imaging control device

10, 10A, 10B, 10C, 10D: imaging control substrate

10a: main surface

20, 20A: imaging substrate

20a: main surface

21, 21A: imaging element

30: anti-vibration unit

K: optical axis

FS1, FS2: flexible printed circuit substrate

F1: first FPC substrate

F2: second FPC substrate

F3: third FPC substrate

F4: fourth FPC substrate

F5: fifth FPC substrate

11A, 11B, 12A: terminal group

11, 11a, 11b: processor

12: power control circuit

13A, 14A, 15A, 16A, 17A: wiring group

13: first control substrate connector

14: second control substrate connector

15: third control substrate connector

16: fourth control substrate connector

17: fifth control substrate connector

18H: opening

22: first imaging substrate connector

22A: fourth imaging substrate connector

23: second imaging substrate connector

23A: fifth imaging substrate connector

24: third imaging substrate connector

L: distance

What is claimed is:

1. An imaging control substrate comprising:
a processor having a plurality of differential signal input terminals into which a signal output from an imaging element is to be input;
a power control circuit that controls electric power supplied to the imaging element;
a first connector to which a power supply line that supplies the electric power controlled by the power control circuit to an imaging substrate mounted with the imaging element is connected;
a second connector to which only a differential signal transmission line that transmits an output signal of the imaging element is connected; and
a wiring group that connects the second connector and the plurality of differential signal input terminals.

2. The imaging control substrate according to claim 1,
wherein the first connector is connected only to the power control circuit.

3. The imaging control substrate according to claim 2,
wherein the imaging substrate mounted with one of a plurality of imaging elements having different power supply currents is connectable, and
an allowable current value of the first connector is equal to or larger than a current value required to be supplied to an imaging element, among the plurality of imaging elements, to which a largest power supply current needs to be supplied.

4. The imaging control substrate according to claim 2, further comprising:
a third connector connected to a terminal of the processor that outputs a control signal of the imaging element.

5. The imaging control substrate according to claim 3, further comprising:
a third connector connected to a terminal of the processor that outputs a control signal of the imaging element.

6. The imaging control substrate according to claim 4,
wherein the third connector is disposed between the first connector and the second connector.

7. The imaging control substrate according to claim 5,
wherein the third connector is disposed between the first connector and the second connector.

8. The imaging control substrate according to claim 1,
wherein a plurality of the second connectors are provided, and
a distance between two adjacent second connectors among the plurality of the second connectors is equal to or larger than a value obtained by multiplying a value of ¼ of a total number of the differential signal transmission line connectable to one of the two adjacent second connectors in which the total number is maximum among the two adjacent second connectors by a width of the differential signal transmission line.

9. The imaging control substrate according to claim 2,
wherein a plurality of the second connectors are provided, and
a distance between two adjacent second connectors among the plurality of the second connectors is equal to or larger than a value obtained by multiplying a value of ¼ of a total number of the differential signal transmission line connectable to one of the two adjacent second connectors in which the total number is maximum among the two adjacent second connectors by a width of the differential signal transmission line.

10. The imaging control substrate according to claim 1,
wherein a plurality of the second connectors are provided, and
a distance between two adjacent second connectors among the plurality of the second connectors is equal to or larger than half of a width in a terminal arrangement direction of one of the two adjacent second connectors in which the width is maximum among the two adjacent second connectors.

11. The imaging control substrate according to claim 2,
wherein a plurality of the second connectors are provided, and
a distance between two adjacent second connectors among the plurality of the second connectors is equal to or larger than half of a width in a terminal arrangement direction of one of the two adjacent second connectors in which the width is maximum among the two adjacent second connectors.

12. The imaging control substrate according to claim 1,
wherein a plurality of the second connectors are provided, and
a distance between two adjacent second connectors among the plurality of the second connectors is equal to or larger than a width of a region, where the plurality of differential signal input terminals connected to one of the two adjacent second connectors are arranged, of the one of the two adjacent second connectors in which the width is maximum among the two adjacent second connectors.

13. The imaging control substrate according to claim 2,
wherein a plurality of the second connectors are provided, and
a distance between two adjacent second connectors among the plurality of the second connectors is equal to or larger than a width of a region, where the plurality of differential signal input terminals connected to one of the two adjacent second connectors are arranged, of the one of the two adjacent second connectors in which the width is maximum among the two adjacent second connectors.

14. The imaging control substrate according to claim 1,
wherein an arrangement direction of a plurality of terminals included in the second connector matches an arrangement direction of the plurality of differential signal input terminals connected to the plurality of terminals included in the second connector.

15. The imaging control substrate according to claim 2,
wherein an arrangement direction of a plurality of terminals included in the second connector matches an arrangement direction of the plurality of differential signal input terminals connected to the plurality of terminals included in the second connector.

16. The imaging control substrate according to claim 1,
wherein a plurality of the processors are provided, and
an arrangement direction of the plurality of differential signal input terminals of each of the plurality of the processors matches an arrangement direction of a plurality of terminals included in the second connector connected to the plurality of differential signal input terminals.

17. The imaging control substrate according to claim 2,
wherein a plurality of the processors are provided, and
an arrangement direction of the plurality of differential signal input terminals of each of the plurality of the processors matches an arrangement direction of a plurality of terminals included in the second connector connected to the plurality of differential signal input terminals.

18. The imaging control substrate according to claim 1, further comprising:
an opening provided in a region between an edge of the imaging control substrate and the second connector,
wherein the differential signal transmission line is inserted into the opening.

19. An imaging control device comprising:
the imaging control substrate according to claim 1;
the imaging substrate mounted with the imaging element; and
a flexible substrate that connects the imaging substrate and the imaging control substrate.

20. The imaging control device according to claim 19,
wherein the imaging control substrate is provided with a plurality of the second connectors, and
the flexible substrate electrically connects at least one of the plurality of second connectors and a connector provided on the imaging substrate.
